(19) United States
(12) Patent Application Publication
(10) Pub. No.: US 2008/0186662 A1
(43) Pub. Date: Aug. 7, 2008

(54) Plasma display device

(76) Inventor: Sang-Gu Lee, Suwon-si (KR)

Correspondence Address: Robert E. Bushnell, Suite 300, 1522 K Street, N.W., Washington, DC, 20005, US

(21) Appl. No.: 11/790,218

(22) Filed: Apr. 24, 2007

(30) Foreign Application Priority Data
Feb. 7, 2007 (KR) 10-2007-0012670

(51) Int. Cl. H05K 5/02

(52) U.S. Cl. 361/681

(57) ABSTRACT

A design for a plasma display device that attenuates noise generated in a flexible printed circuit (FPC) so that the noise does not reach the chassis base, the FPC connecting a printed circuit board assembly to electrodes within the plasma display panel. The plasma display device includes a spacer made out of non woven fabric and located between the FPC and the chassis.

### CLAIM OF PRIORITY

This application makes reference to, incorporates the same herein, and claims all benefits accruing under 35 U.S.C. §119 from an application for PLASMA DISPLAY DEVICE earlier filed in the Korean Intellectual Property Office on 7 Feb. 2007 and there duly assigned Serial No. 10-2007-0012670.

### BACKGROUND OF THE INVENTION

1. Field of the Invention

The present invention relates to a plasma display device, and more particularly, to a plasma display device capable of reducing the transfer of noise from a flexible printed circuit (FPC) to a chassis base, the FPC connecting printed circuit board assemblies to electrodes of the plasma display panel.

2. Description of the Related Art

Generally, a plasma display device includes a plasma display panel for displaying an image, a chassis base which is fixed to the plasma display panel to support the plasma display panel, and a plurality of printed circuit board assemblies, which are mounted on the chassis base and electrically connected to the plasma display panel. The plasma display panel generates plasma through gas discharge and excites phosphors by using vacuum ultra-violet (VUV) rays emitted from the plasma, thereby displaying an image by using visible light of red (R), green (G), or blue (B) obtained by stabilizing the excited phosphors.

Since the plasma display panel seals two facing glass substrates together, and since a discharging space is formed between the glass substrates, the plasma display panel has weak mechanical rigidity with respect to external impact. Accordingly, the chassis base is made out of a metal that has a mechanical rigidity that is larger than that of the glass substrates to support the plasma display panel. The chassis base has functions of supplying a space for mounting the printed circuit board assemblies, radiating heat from the plasma display panel, and grounding electromagnetic interference (EMI), in addition to the function of supplying the mechanical rigidity for supporting the plasma display panel.

Moreover, in order to perform the aforementioned functions, the plasma display panel is fixed to a front surface of the chassis base by interposing a double sided tape therebetween. The printed circuit board assemblies are mounted on a rear surface of the chassis base. A plurality of bosses are formed on the rear surface of the chassis base, the printed circuit board assemblies are disposed on the bosses, and set screws are engaged with the bosses through the printed circuit board assemblies. Accordingly, the printed circuit board assemblies are mounted on the chassis base.

The plasma display device includes the plurality of printed circuit board assemblies in order to perform each function for driving the plasma display panel. Specifically, the printed circuit board assemblies include a sustain board assembly for controlling sustain electrodes, a scan board assembly for controlling scan electrodes, and an address buffer board assembly for controlling address electrodes.

The printed circuit board assemblies include an image processing/control board assembly, which receives image signals from an outside of the plasma display device and generates control signals for driving the address electrodes and control signals for driving the sustain and scan electrodes, to apply the control signals to the corresponding board assemblies. In addition, the printed circuit board assemblies include a power board assembly for supplying power needed for driving the aforementioned board assemblies.

The sustain board assembly is connected to the sustain electrodes, which are drawn out from the inside of the plasma display panel through flexible printed circuits (FPC) and connectors. The scan board assembly is connected to the scan electrodes, which are drawn out from the inside of the plasma display panel through FPCs and connectors. The address buffer board assembly is connected to the address electrodes, which are drawn out from the inside of the plasma display panel through FPCs and connectors.

The FPC, for connecting the address buffer board assembly and the address electrodes, includes a driver integrated circuit (IC) package. A driver IC, for generating an address pulse to be applied to the address electrodes, is mounted on the driver IC package. The driver IC package can be a tape carrier package (TCP).

The driver IC package is disposed at a long side of the plasma display panel having two facing long sides and two facing short sides. The driver IC package is bent so that both ends of the driver IC package electrically connect the plasma display panel on the front side of the chassis base to the address buffer board assembly on the rear side of the chassis base. The driver IC package or the FPC includes two films, which adhere to each other, and a metal circuit pattern formed therebetween. The circuit pattern applies a voltage and a current between the printed circuit board assemblies and the electrodes of the plasma display panel. In order to drive the plasma display panel, an alternating current AC is applied for reset, address, and sustain periods. When voltages applied during the reset, address, and sustain periods change, the driver IC package or the FPC vibrates. The vibration generates interference by contacting the film that is an outer surface of the FPC to an edge portion of the chassis base. Accordingly, noise occurs. What is therefore needed is a design for a plasma display device that eliminates the negative effects of noise generated by the FPC.

### SUMMARY OF THE INVENTION

The present invention provides a plasma display device capable of reducing noise transfer from a flexible printed circuit (FPC) to the chassis base, the FPC connecting printed circuit board assemblies to electrodes of the plasma display panel.

According to an aspect of the present invention, there is provided a plasma display device including a plasma display panel adapted to display an image and including a plurality of electrodes arranged between a pair of substrates, a chassis base fixed to the plasma display panel and adapted to support the plasma display panel, a printed circuit board assembly mounted on the chassis base and a FPC (flexible printed circuit) connecting the printed circuit board assembly to the plurality of electrodes, wherein the chassis base includes a main chassis having a plate shape and having two facing long sides and two facing short sides perpendicular to the long sides and a sub chassis combined with at least one of one of said two long sides and said two short sides of the main chassis, wherein the FPC surrounds the sub chassis and the at least one of said sides of the main chassis combined with the sub chassis, and wherein a spacer is arranged between the FPC and the sub chassis.

The spacer can include a nonwoven fabric. The at least one of said two long sides and said two short sides of the main chassis being a bent portion that is bent towards the printed circuit board, wherein the sub chassis is bent to surround the bent portion of the main chassis and have first and second surfaces in parallel with the bent portion of the main chassis, and wherein the sub chassis also has a third surface connecting first surface to the second surface, the third surface adhering to an end portion of the bent portion of the main chassis. The spacer can be adhered closely to at least one of the first, second, and third surfaces of the sub chassis. The spacer can adhere closely to the third surface of the sub chassis. The spacer can adhere closely to the second surface of the sub chassis. The spacer can adhere to at least one of an edge between the first and third surfaces and an edge between the second and third surfaces of the sub chassis.

The plasma display device can also include comprising a driver IC (integrated circuit) mounted on the FPC and facing the second surface of the sub chassis. The plasma display device can also include thermal grease arranged between the driver IC and the second surface of the sub chassis and a thermally conductive pad attached to a side of the driver IC opposite to that of the thermal grease. The plasma display device can also include a cover plate covering the FPC, supporting the thermally conductive pad and adhering to the third surface of the sub chassis. The plurality of electrodes can include a plurality of address electrodes extending in a direction perpendicular to a plurality of discharge electrodes. The FPC can include a tape carrier package, the plasma display device further comprising a driver IC (integrated circuit) mounted on the FPC. The second and third surfaces of the sub chassis can be connected to each other in a shape of curve. The spacer can be adapted to prevent vibrational noise generated in the FPC from reaching either the chassis or the sub chassis.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a perspective view of a plasma display device according to an embodiment of the present invention;

FIG. 2 is an exploded perspective view illustrating a sub chassis, a spacer, and a cover plate of the plasma display device of FIG. 1;

FIG. 3 is a cross sectional view taken along line III-III of FIG. 1; and

FIG. 4 illustrates a function of the spacer between the sub chassis and the flexible printed circuit of the plasma display device of FIG. 1.

### DETAILED DESCRIPTION OF THE INVENTION

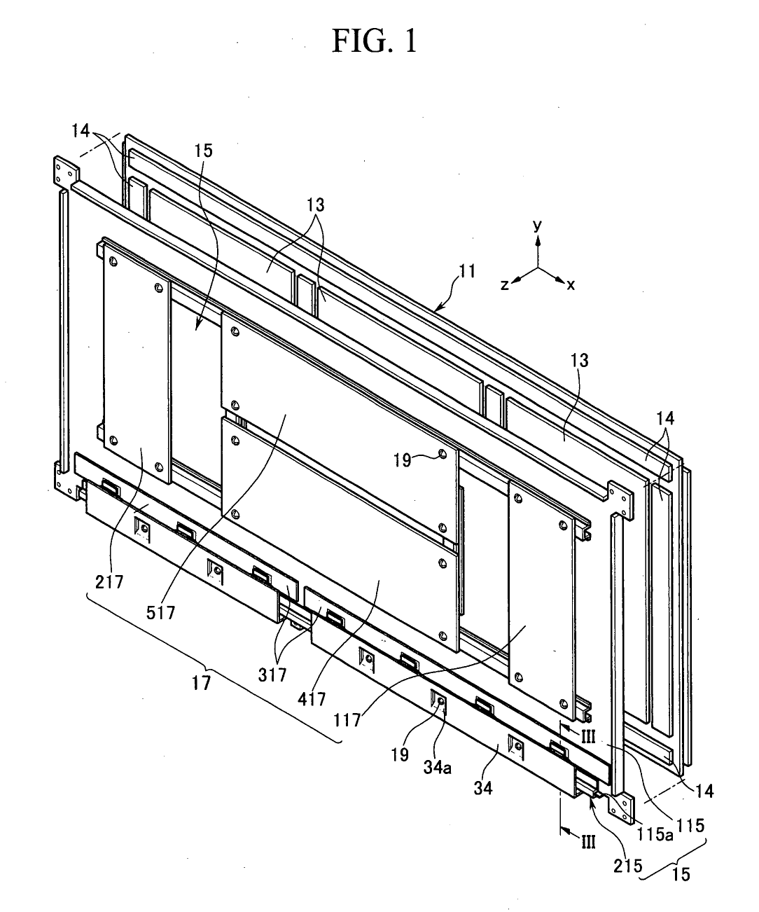

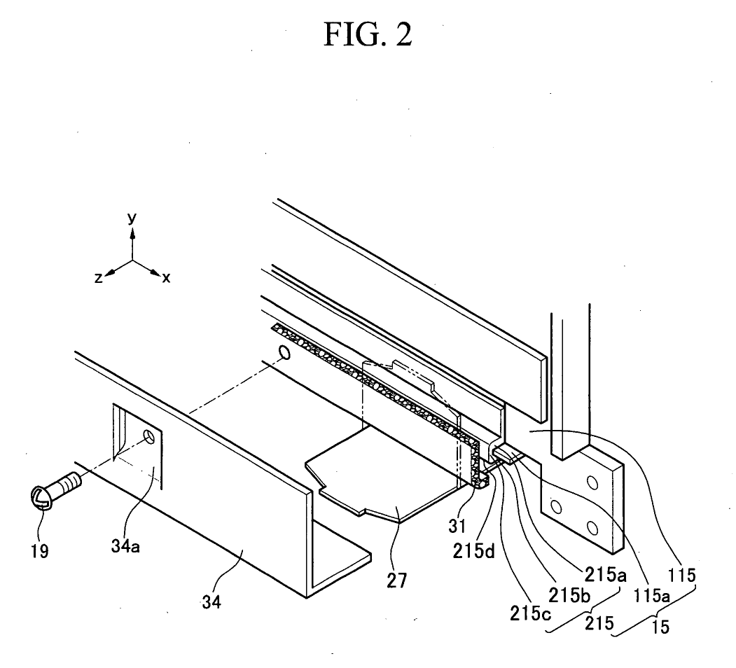

Turning now to FIGS. 1 and 2, FIG. 1 is a perspective view of a plasma display device according to an embodiment of the present invention and FIG. 2 is an exploded perspective view illustrating a sub chassis, a spacer, and a cover plate of the plasma display device of FIG. 1. Referring to FIGS. 1 and 2, the plasma display device includes a plasma display panel 11 for displaying an image using gas discharge, heat dissipating sheets 13, a chassis base 15, and printed circuit board assemblies 17.

The heat dissipating sheets 13 are disposed on a rear surface of the plasma display panel 11. The heat dissipating sheets 13 conduct and diffuse heat in a planar direction generated in the plasma display panel 11 due to gas discharge. In order to conduct and diffuse the heat generated in the plasma display panel 11, the heat dissipating sheets 13 are made out of an acrylic heat dissipating material, a graphite heat dissipating material, a metallic heat dissipating material, or a carbon nano tube heat dissipating material.

The chassis base 15, including the heat dissipating sheets 13 on the front surface thereof, is adhered to the rear surface of the plasma display panel 11 using a double sided tape 14 to support the plasma display panel 11. In addition, the chassis base 15, including the printed circuit board assemblies 17 on the rear surface of the plasma display panel 11, supports the plasma display panel 11. As described above, the chassis base 15 has enough mechanical rigidity to support the plasma display panel 11 and the printed circuit board assemblies 17.

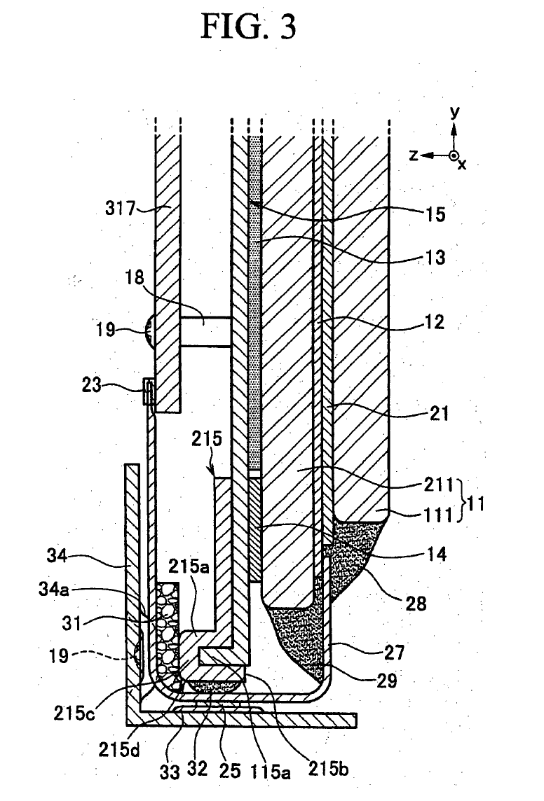

Referring now to FIG. 3, although the heat dissipating sheets 13 are illustrated to be adhered to the chassis base 15, a minute space (not shown) may be formed therebetween. Accordingly, most of the heat generated in plasma display panel 11 diffuses and radiates through the heat dissipating sheets 13. The printed circuit board assemblies 17 are mounted at predetermined positions on the rear surface of the chassis base 15 and drive the plasma display panel 11. The plasma display panel 11 and the printed circuit board assemblies 17 are adhered to the front and rear surfaces of the chassis base 15, respectively, and electrically connected to one another in order to continuously display images.

The printed circuit board assemblies 17 can be disposed on a plurality of bosses 18 on the chassis base 15 and fixed by set screws 19 to be engaged with the bosses 18 (refer to FIG. 3). In addition, the printed circuit board assemblies 17 are formed to be separated from each other to perform functions for driving the plasma display panel 11, respectively. Specifically, the printed circuit board assemblies 17 includes a sustain board assembly 117 for controlling sustain electrodes (not shown), a scan board assembly 217 for controlling scan electrodes (not shown), and an address buffer board assembly 317 for controlling address electrodes 12.

The printed circuit board assemblies 17 include an image processing/control board assembly 417, which receives an image signal from the outside of the plasma display device and generates control signals for driving the address electrodes 12 and control signals for driving the sustain and scan electrodes to apply the control signals to the corresponding board assemblies. In addition, the printed circuit board assemblies 17 include a power board assembly 517 for supplying power needed for driving the board assemblies 117, 217, 317, and 417.

The sustain board assembly 117 is connected to the sustain electrodes through a flexible printed circuit (FPC) (not shown). The scan board assembly 217 is connected to the scan electrodes through an FPC (not shown). The address buffer board assembly 317 is connected to the address electrodes 12 through the FPC 27. As shown in FIG. 3, the address buffer board assembly 317 is disposed on the bosses 18 on the chassis base 15 and fixed by set screws 19 to be engaged with the bosses 18.

The embodiment relates to connection between the plasma display panel 11 for displaying an image and other components such as the printed circuit board assemblies 17 or chassis base 15. Accordingly, the detailed description about the plasma display panel 11 will be omitted. As only the part related to the embodiment is described, the plasma display panel 11 includes electrodes for gas discharge. In FIG. 3, sustain and scan electrodes are omitted while the address electrode 12 is shown.

A connection structure between the address buffer board assembly 317 and the address electrodes 12 through the FPC 27 can be applied to a connection structure between the sustain board assembly 117 and the sustain electrodes through the FPC and a connection structure between the scan board assembly 217 and the scan electrodes through the FPC. Accordingly, in the embodiment, the connection structure between the sustain board assembly 117 and the sustain electrodes and the connection structure between the scan board assembly 217 and the scan electrode are not shown. However, the connection structure between the address buffer board assembly 317 and the address electrodes 12 is exemplified. Hereinafter, the exemplified connection structure will be mainly described.

The chassis base 15 is firstly described before description of the connection structure. For example, the chassis base 15 includes a main chassis 115 and a sub chassis 215. The main chassis 115 has a plate shape including two facing long sides and two facing short sides perpendicular to the long sides. The sub chassis 215 is combined with at least one side of the main chassis 115. The main chassis 115 includes a bent portion 115a which is bent towards the printed circuit board assembly 17 at at least one side of the main chassis 115. Referring to FIG. 1, the main chassis 115 includes bent portions 115a in four sides thereof and includes sub chassis 215 at one of the bent portions 115a.

Referring to FIGS. 2 and 3, the sub chassis 215 has a structure that combines with the bent portion 115a of the main chassis 115. For example, the sub chassis 215 includes first, second, and third surfaces 215a, 215b, and 215c which are bent to correspond to the bent portion 115a of the main chassis 115. The first and second surfaces 215a and 215b are formed in parallel with the bent portion 115a and perpendicular to the main chassis 115. The first surface 215a is connected to the second surface 215b through the third surface 215c. Therefore, the third surface 215c adheres closely to the bent portion 115a when the sub chassis 215 is combined with the main chassis 115 and is in parallel with the main chassis 115.

The FPC 27 surrounds one side of the main chassis 115 and the sub chassis 215 combined with the side of the main chassis 115. The ends of the FPC 27 are connected to the address electrode 12 and the address buffer board assembly 317, respectively (refer to FIG. 3). The driver IC 25, for generating the control signals to be applied to the address electrode 12, is mounted on the FPC 27 that connects the address electrode 12 to the address buffer board assembly 317. For example, the FPC 27 can be a tape carrier package (TCP).

The address electrode 12 is covered with a dielectric layer 21. The dielectric layer 21 is formed between the front and rear substrates 111 and 211, which face each other and are partially offset from each other, to the extent of the offset portion (a portion outside the front substrate 111).

A terminal of the FPC 27 is connected to the address electrode 12 formed outside of the dielectric layer 21. The other terminal of the FPC 27 is connected to a connector 23 included in the address buffer board assembly 317. Referring to FIG. 3, a first sealing material 28 is supplied to an end of the front substrate 111, on which the address electrode 12 is connected to the FPC 27, and the FPC 27. A second sealing material 29 is supplied to an end of the rear substrate 211 and the FPC 27, which are located on the side opposite to the first sealing material 28. The first and second sealing materials 28 and 29 prevent moisture and impurities from being introduced into the connection portion between the address electrode 12 and the FPC 27.

The FPC 27 applies a driving voltage and a current generated in the address buffer board assembly 317 to the address electrode 12 when the plasma display panel 11 is driven. When the voltage and the current change, a vibration occurs. In addition, the vibration generates noise between the FPC 27 and the sub chassis 215.

Referring to FIGS. 2 and 3, a spacer 31 is disposed between the FPC 27 and the sub chassis 215. The spacer 31 is constructed to attenuate noise generated by the FPC 27 before it reaches the sub chassis 215 by absorbing the vibration of the FPC 27. For example, the spacer 31 is made out of a nonwoven fabric to dampen the vibration of the FPC 27 and absorb the noise between the FPC 27 and the sub chassis 215. The spacer 31 adheres closely to at least one surface among the first, second, and third surfaces 215a, 215b, and 215c of the sub chassis 215 and attenuates the vibration so that it is not transmitted from the FPC 27 to the sub chassis 215.

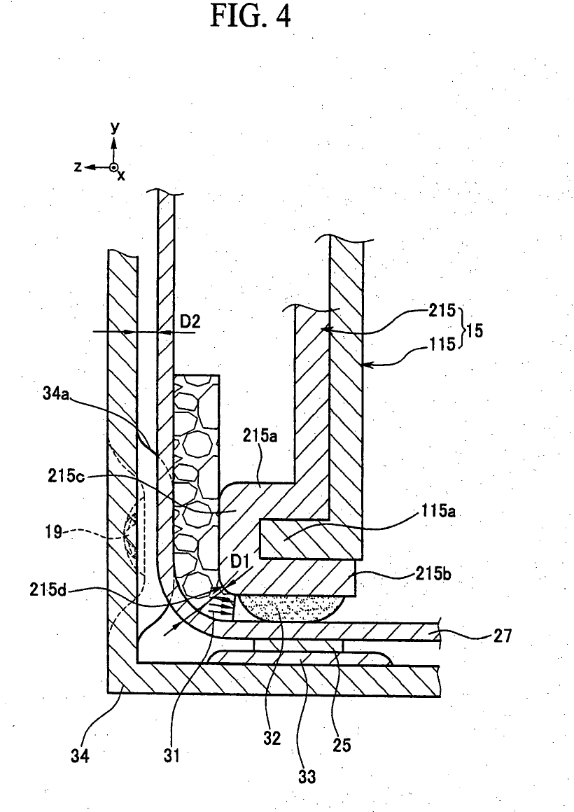

Referring to FIGS. 3 and 4, the spacer 31 adheres closely to the third surface 215c. In addition, the spacer 31 partially adheres closely to the second surface 215b. Specifically, the spacer 31 is disposed at the portion in which the FPC 27 may be closest to the sub chassis 215 (separated by distance D1) due to the bent shape of the FPC 27 through which the address electrode 12 is connected to the address buffer board assembly 317. Accordingly, the FPC 27 and the sub chassis 215 are spaced apart from each other. The space is filled with the spacer 31.

For example, the spacer 31 can adhere close to an edge 215d formed by the second and third surfaces 215b and 215c of the sub chassis 215. Accordingly, the spacer 31 prevents noise from FPC 27 from crossing the distance D1 and reaching the edge between the second and third surfaces 215b and 215c of the sub chassis 215. In addition, since the second and third surfaces 215b and 215c of the sub chassis 215 are connected to each other in a shape of edge 215d, the edge 215d therebetween is formed as the curve. The curved edge 215d can effectively prevent the interference with the FPC 27.

At this time, the driver IC 25 mounted on the FPC 27 is disposed corresponding to the second surface 215b of the sub chassis 215. Since the second surface 215b is larger than the third surface 215c, the driver IC 25 can be stably located thereat. Then, thermal grease 32 is interposed between the driver IC 25 and the second surface 215b allow heat generated in the driver IC 25 to conduct to the sub chassis 215 at the second surface 215b. A portion of the spacer 31 corresponding to the second surface 215b and the edge 215d prevents the thermal grease 32 from spreading out to the third surface 215c, thereby preventing the heat dissipating performance of the thermal grease 32 from deteriorating. In addition, the thermally conductive pad 33 is disposed on a side of the driver IC opposite to the thermal grease 32. The thermally conductive pad 33 adheres closely to the driver IC 25 to protect the driver IC 25 and absorb the heat generated by the driver IC 25.

A cover plate 34 supports the thermally conductive pad 33 and covers the FPC 27 and is mounted on the third surface 215c of the sub chassis 215 by using the set screws 19. The cover plate 34 has a length that extends along the long side of the chassis base 15 to cover the plurality of FPCs 27. The cover plate 34 includes a protrusion 34a which protrudes toward the spacer 31. Referring to FIG. 4, the protrusion 34a is supported by the spacer 31 to allow the cover plate 34 and the FPC 27 to be spaced apart by a distance D2, thereby preventing the FPC 27 from interfering with the cover plate 34, even when the FPC 27 vibrates.

As described above, according to the plasma display device according to an embodiment of the present invention, the chassis base is formed by combining the main chassis with the sub chassis at one side of the main chassis, and the spacer is interposed between the sub chassis and the FPC, thereby preventing the vibrations produced in the FPC from reaching the sub chassis. Accordingly the noise generated in the FPC can be attenuated before reaching the sub chassis.

While this invention has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A plasma display device, comprising:
a plasma display panel adapted to display an image and including a plurality of electrodes arranged between a pair of substrates;
a chassis base fixed to the plasma display panel and adapted to support the plasma display panel;
a printed circuit board assembly mounted on the chassis base; and
a FPC (flexible printed circuit) connecting the printed circuit board assembly to the plurality of electrodes, wherein the chassis base includes
a main chassis having a plate shape and having two facing long sides and two facing short sides perpendicular to the long sides; and
a sub chassis combined with at least one of one of said two long sides and said two short sides of the main chassis, wherein the FPC surrounds the sub chassis and the at least one of said sides of the main chassis combined with the sub chassis, and wherein a spacer is arranged between the FPC and the sub chassis.

2. The plasma display device of claim 1, wherein the spacer is comprised of a nonwoven fabric.

3. The plasma display device of claim 1, wherein said at least one of said two long sides and said two short sides of the main chassis being a bent portion that is bent towards the printed circuit board, wherein the sub chassis is bent to surround the bent portion of the main chassis and have first and second surfaces in parallel with the bent portion of the main chassis, and wherein the sub chassis also has a third surface connecting first surface to the second surface, the third surface adhering to an end portion of the bent portion of the main chassis.

4. The plasma display device of claim 3, wherein the spacer adheres closely to at least one of the first, second, and third surfaces of the sub chassis.

5. The plasma display device of claim 3, wherein the spacer adheres closely to the third surface of the sub chassis.

6. The plasma display device of claim 5, wherein the spacer adheres closely to the second surface of the sub chassis.

7. The plasma display device of claim 3, wherein the spacer adheres to at least one of an edge between the first and third surfaces and an edge between the second and third surfaces of the sub chassis.

8. The plasma display device of claim 3, further comprising a driver IC (integrated circuit) mounted on the FPC and facing the second surface of the sub chassis.

9. The plasma display device of claim 8, further comprising:
thermal grease arranged between the driver IC and the second surface of the sub chassis; and
a thermally conductive pad attached to a side of the driver IC opposite to that of the thermal grease.

10. The plasma display device of claim 9, further comprising a cover plate covering the FPC, supporting the thermally conductive pad and adhering to the third surface of the sub chassis.

11. The plasma display device of claim 3, wherein the plurality of electrodes includes a plurality of address electrodes extending in a direction perpendicular to a plurality of scan and sustain electrodes.

12. The plasma display device of claim 11, wherein the FPC comprises a tape carrier package, the plasma display device further comprising a driver IC (integrated circuit) mounted on the FPC.

13. The plasma display device of claim 3, wherein the second and third surfaces of the sub chassis are connected to each other in a shape of curve.

14. The plasma display device of claim 1, the spacer being adapted to prevent vibrational noise generated in the FPC from reaching either the chassis or the sub chassis.
